(19) United States
(12) Patent Application Publication
(10) Pub. No.: US 2009/0218638 A1
(43) Pub. Date: Sep. 3, 2009

(54) NAND FLASH PERIPHERAL CIRCUITRY FIELD PLATE

(76) Inventor: Michael A. Smith, Boise, ID (US)

Correspondence Address: COOL PATENT, P.C.;c/o CPA Global, P.O. BOX 52050, MINNEAPOLIS, MN, 55402, US

(21) Appl. No.: 12/040,424

(22) Filed: Feb. 29, 2008

(51) Int. Cl. H01L 21/336; H01L 29/78

(52) U.S. Cl. 257/409; 438/289; 257/E21.409; 257/E29.266

(57) ABSTRACT

A high voltage device for use in periphery circuitry of a NAND flash memory device comprising a field plate.

### BACKGROUND

Flash electrically-erasable programmable read only memory (EEPROM) devices may be used for many purposes in present day digital circuits such as computers because of their ability to retain data when power is removed and to be easily reprogrammed. A flash EEPROM device may comprise a floating gate field effect transistor array and peripheral circuitry. The charge stored on the floating gate may be changed by programming and the condition (programmed or erased) may be detected by sensing the devices such as cells.

### BRIEF DESCRIPTION OF THE DRAWINGS

FIG. 1 is a section view of a particular embodiment of a high voltage device.

FIG. 2 is a block diagram illustrating a process for making a particular embodiment of a high voltage device and illustrations depicting a process flow.

FIG. 3 is a plan view of a particular embodiment of a mask for use in a process for making a particular embodiment of a high voltage device.

FIG. 4 is a plan view of a particular embodiment of a mask for use in a process for making a particular embodiment of a high voltage device.

FIG. 5 is a plan view of a particular embodiment of a mask for use in a process for making a particular embodiment of a high voltage device.

FIG. 6 is a plan view of a particular embodiment of a juxtaposition of three masks for use in a process for making a particular embodiment of a high voltage device.

### DETAILED DESCRIPTION

In the following detailed description, numerous specific details are set forth in order to provide a thorough understanding of claimed subject matter. However, it will be understood by those skilled in the art that claimed subject matter may be practiced without these specific details. In other instances, well-known methods, procedures, and components have not been described in detail so as not to obscure claimed subject matter.

Throughout the following disclosure the term ‘NAND’ is used and is intended to refer to the logic function ‘not-AND’. The term ‘NAND flash’ is used throughout the disclosure and is intended to refer to a flash EEPROM device that employs tunnel injection for writing and tunnel release for erasing.

Particular embodiments of high voltage (HV) devices described herein comprise a set of implant conditions that provide an n-channel metal oxide semiconductor (NMOS) type device. When an HV device is an NMOS type device the substrate may be p-type, a voltage threshold (Vt) implant may be p-type, and drain extension region (DER) and source/drain (S/D) implants may be n-type. However, in other particular embodiments the implant conditions may be inverted to provide a p-channel metal oxide semiconductor (PMOS) device and claimed subject matter is not so limited. In a particular embodiment, a p-type dopant may be Boron, and an n-type dopant may be Phosphorous or Arsenic and claimed subject matter is not limited in this regard.

NAND flash EEPROM memory devices may have a core region comprising a memory array surrounded by a peripheral region comprising circuitry. In a particular embodiment, the peripheral region may comprise circuitry including field effect transistors (FET). The peripheral circuitry operates the array providing the voltage to the array to perform the read, write, and erase operations. Additionally, the peripheral circuitry provides input/output operations and all logic processing associated with these operations. Certain array operations, such as program and erase, require the periphery circuitry to provide high voltages to the array, typically in the 20V-30V range, which requires that certain transistors in the periphery circuitry be able to reliably withstand voltages in this range. Such transistors are referred to as high voltage (HV) field effect transistors (FETs). HV FETs comprise relatively large dimensions and may consume much of the area of the silicon substrate. The industry standard design for these HV FETs provides a relatively large space between the channel gate edge and the drain and source contacts, often referred to as the drain extension region (DER). The DER is relatively lightly doped so as to deplete with applied high drain voltage (Vd) due to the vertical DER-to-substrate electric field, thereby reducing the maximum lateral drain-to-gate electric field and increasing the drain breakdown voltage (Bvdss). This is the so-called Reduced Surface Field (ReSurF) effect. In addition to the silicon area consumed directly by the DER, the relative light doping of the DER results in relatively high resistance of the DER, thereby decreasing the on current (Idss) that the HV device can provide. Therefore, in order to provide Idss needed to provide the desired functionality in the circuit, the device must be made relatively wide.

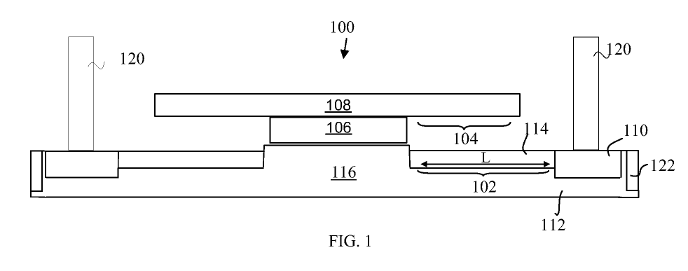

FIG. 1 illustrates a section view of a particular embodiment of a HV device 100 for incorporation into the peripheral circuitry of a NAND flash device. In a particular embodiment, HV device 100 may be used in a NAND flash EEPROM device having a drain Bvdss requirement in the range of 20V-30V. However, this is merely an example of a Bvdss range and claimed subject matter is not limited in this regard.

In a particular embodiment, HV device 100 may comprise substrate 112, DER 102, first gate 106, second gate material layer 108 comprising field plate 104, S/D implant 110, S/D contacts 120, DER implant 114 and isolation trench 122. According to a particular embodiment, the presence of field plate 104 over DER 102 in HV device 100 may generate an enhanced ReSurF effect. Such an enhanced ReSurF effect may enable an improved tradeoff between the DER 102 resistance and the Bvdss. In other words, in a particular embodiment, an enhanced ReSurF effect may enable decreasing the length L of DER 102 with respect to conventional DER lengths while maintaining Bvdss, for instance, at approximately 20 V to about 30 V. The presence of field plate 104 decreases the effective DER doping by generating a vertical electrical field between DER 102 and field plate 104 during high Vd/low Vg biases such as when the device is off and holding high drain biases, for example. During such a bias condition, this electric field may contribute to depletion of carriers in the DER 102 region, thereby decreasing the effective doping level. When the device is in ‘on’ (high Vg bias; Vg>=Vd), the electrical field between field plate 104 and DER 102 may be substantially eliminated or even reversed, thus the effective doping in DER 102 may not be decreased, but possibly even increased, so that DER 102 may have relatively low resistance and Idss may not decrease.

According to a particular embodiment, decreasing length L of a DER 102 may enable decreasing the dimensions of a NAND flash EEPROM device incorporating HV device 100 into its peripheral circuitry while maintaining breakdown voltage requirements. In a particular embodiment, the enhanced ReSurF effect enables shortening length L of DER 102 from about 0.35 microns to about 0.25 microns while maintaining the same Bvdss. However, this is merely an example of a length of a DER and claimed subject matter is not so limited.

In another particular embodiment, an enhanced ReSurF effect may enable increasing the amount of impurities implanted during formation of DER 102. Such an increase may decrease resistance of DER 102 and increase Idss. Such increased Idss may enable reducing DER 102 width as well.

In a third embodiment, an enhanced ReSurF effect may both enable increased impurity implant of DER 102 (to decrease width) and decreasing length L of DER 102. Thus the overall footprint of HV device 100 may be reduced with respect to conventional HV devices.

In a particular embodiment, formation of field plate 104 may be integrated into a standard process flow. In a standard process, the dimensions of a first gate layer and second gate layer may be defined, followed by an impurity implant to define DER 102. However, to integrate formation of field plate 104 such that it extends over DER 102, a DER implant step may be moved to a point in the process flow after gate material for first gate 106 is deposited and before second gate material 108 is deposited.

In a particular embodiment, field plate 104 may be formed by a variety of processes. For instance, in a particular embodiment, first gate 106 may be formed by an etch step followed by an implant step wherein etching first gate 106 and implanting DER 102 may take place using different masks. In another particular embodiment, etching to define first gate 106 may be combined with DER 102 implant in a single step using a single mask (hereinafter referred to as ‘combined etch and implant step’).

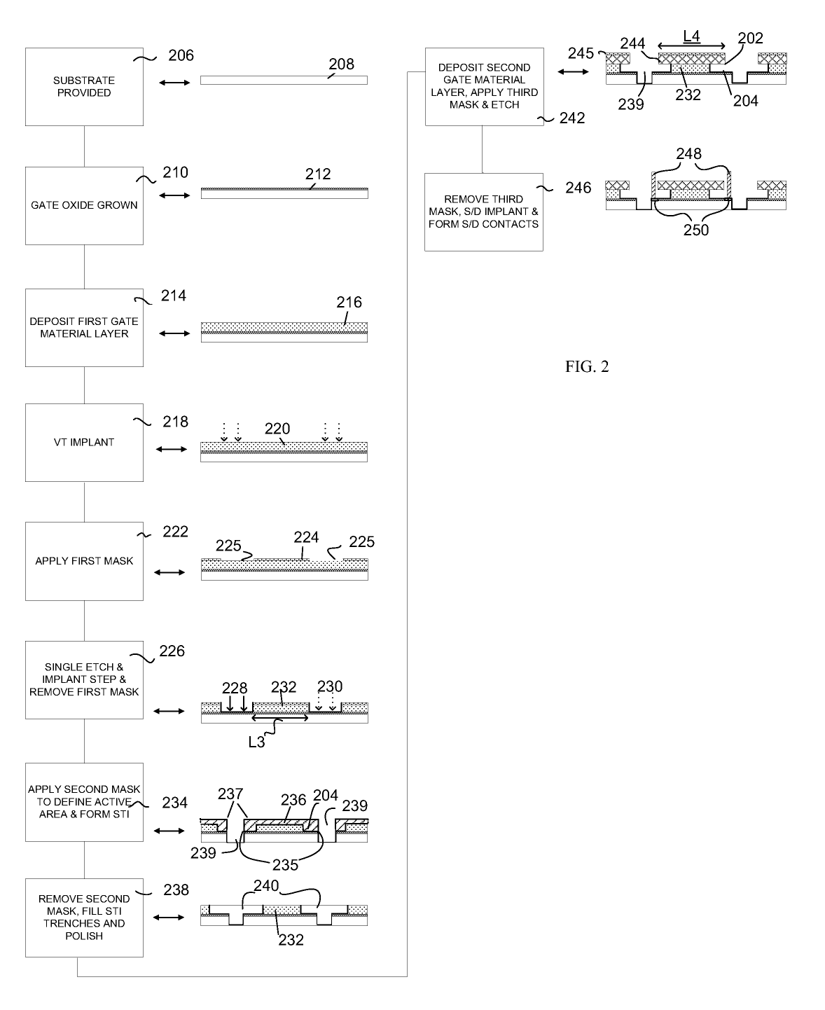

In a particular embodiment, combining a first gate 106 etch and DER 102 implant in a single step may enable formation of field plate 104 with minimal changes to a standard process flow and without increasing the mask count. The mask count may remain unchanged because a single mask may be used in the combined etch and implant step. Further explanation of a process for making HV device 100 is provided below with reference to FIG. 2.

FIG. 2 is a block diagram illustrating a particular embodiment of process 200 to form an HV device comprising at least one field plate 202 positioned over DER 204. In FIG. 2 each process block is paired with an illustration to show the process step.

In a particular embodiment, process 200 may begin at block 206 where substrate 208 may be provided. According to a particular embodiment, substrate 208 may comprise a variety of materials such as, for instance, any of a variety of semiconductor materials including silicon and/or germanium and claimed subject matter is not so limited.

In a particular embodiment, process 200 may flow to block 210 where gate dielectric 212 may be grown. According to a particular embodiment, gate oxide 212 may comprise a variety of materials, such as, for instance, silicon dioxide, silicon nitride and/or polysilicon and claimed subject matter is not so limited.

In a particular embodiment, process 200 may flow to block 214 where first gate material layer 216 may be deposited. According to a particular embodiment, first gate material layer 216 may comprise a variety of materials, such as, for instance, polysilicon and claimed subject matter is not so limited. In a particular embodiment, if polysilicon is used, it may be doped with impurities to make it conductive. Alternative gate materials include metals, such as aluminum and/or tungsten and claimed subject matter is not so limited.

According to a particular embodiment, process 200 may flow to block 218 where a voltage threshold (Vt) implant may proceed. Such a Vt implant may be deposited near the surface of substrate 208 through first gate material layer 216. In a particular embodiment, Vt implant may comprise implantation of one or more impurities into gate material layer 216. According to a particular embodiment, such impurities may be a p-type or n-type and claimed subject matter is not so limited. Alternatively, Vt implant may be performed at other locations and/or in other steps and claimed subject matter is not limited in this regard.

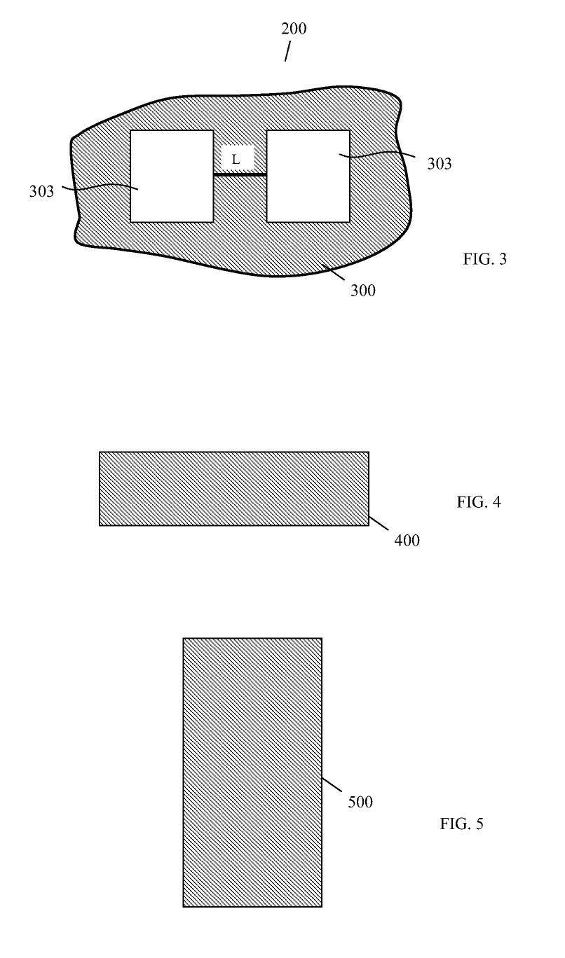

In a particular embodiment, process 200 may flow to block 222 where first mask 224 may be applied over first gate material layer 216. According to a particular embodiment, first mask 224 may comprise openings 225. A plan view of a particular embodiment of first mask 224 is illustrated in FIG. 3.

Referring still to FIG. 2, in a particular embodiment, process 200 may flow to block 226 where a polysilicon etch 228 and DER implant 230 may proceed in a single process step though openings 225. Such a single etch and implant step may form a drain extension region defining polysilicon gate 232 length L3. According to a particular embodiment, polysilicon etch 228 may proceed via a variety of methods, such as, via plasma dry etching, and/or wet etch and claimed subject matter is not limited in this regard. According to a particular embodiment, DER implant 230 may follow polysilicon etch 228 also using first mask 224. Implant ions may comprise a variety of materials, such as, for instance, Boron, Arsenic and/or Phosphorus and claimed subject matter is not limited in this regard. According to a particular embodiment, a substantially greater concentration of ions may be implanted to enable decreasing the width (not shown) of DER 204 to about 0.25 microns. Increasing the ion dose into DER 204 may modulate the carrier depletion occurring in DER 204 and may enhance the ReSurF effect. For instance, the increased ion dose may be in the range of 1×10̂12 per cm̂2 to about 1×10̂13 per cm̂2. Re-using first mask 224 and performing DER implant 230 here supplants an additional DER implant step requiring the use of another mask. Therefore, the final mask count of the process 200 may not be increased over a standard process flow. However, in another particular embodiment more than one mask may be used to perform polysilicon etch 228 and DER implant 230 and claimed subject matter is not so limited.

In a particular embodiment, at block 234, second mask 236 comprising photoresist may be applied to define active area boundaries 235 and shallow trench isolation (STI) boundaries 237. In a particular embodiment, such active area boundaries 235 and STI boundaries 237 may be the same structure. In a particular embodiment, STI trenches 239 may be formed after second mask 236 is applied. In a particular embodiment, second mask 236 may be juxtaposed with first mask 224 such that openings 225 of first mask 224 extend beyond DER 204 active area. In a particular embodiment, a portion of first mask 224 between openings 225 having length L3 defines first gate 232 length. A plan view of a particular embodiment of second mask 236 is illustrated in FIG. 4.

Referring still to FIG. 2, in a particular embodiment, process 200 may flow to block 238 where second mask 236 may be remove exposing first gate 232. After removing second mask 236, in a particular embodiment, STI fill 240 may be deposited in STI trenches 239 and over active area, DER 204. In a particular embodiment, STI fill 240 may comprise a variety of known fill materials such as an oxide and claimed subject matter is not so limited. According to a particular embodiment, a polish step may then be carried out using any of a variety of methods, such as, chemical mechanical polishing (CMP) or other known methods of polishing and claimed subject matter is not so limited. Alternatively, a wet dip may be carried out after CMP in order to adjust the height of the field plate to be formed. In a particular embodiment, a wet dip may recess STI fill 240 below the level of gate material layer 216 enabling adjustment of the height of the field plate to be formed.

In a particular embodiment, process 200 may flow to block 242 where second gate material layer 244 may be deposited over first gate 232 and oxide filled STI trenches 239. According to a particular embodiment, second gate material layer 244 may comprise a variety of materials, such as, for instance, polysilicon and claimed subject matter is not so limited. In a particular embodiment, if polysilicon is used, it may be doped with impurities to make it conductive. Alternative gate materials include metals, such as aluminum and/or tungsten and claimed subject matter is not so limited.

In a particular embodiment, third mask 245 may be applied over second gate material layer 244 and may cover a portion of second gate material layer 244 in the gate region above first polysilicon gate 232. In a particular embodiment, second gate material layer 244 may be patterned or etched through third mask 245 by a variety of methods to form field plate 202 extending over DER 204. As discussed above, field plate 202 may be capable of generating an enhanced ReSurF effect enabling shortened DER 204 to maintain a Bvdss in the range of 20V-30V. In a particular embodiment, length L4 of the portion of second gate material layer 244 covered by mask 245 may be longer than the length L3 of first polysilicon gate 232 in order to form field plate 202 over DER 204. In a particular embodiment, field plate 202 may not extend to active area boundaries 235 in order to make room for S/D contacts. However, in another particular embodiment, an arrangement with “buried contacts” wherein source and drain regions are contacted from a remote location via S/D diffusion regions may enable extending field plate 202 to active area boundaries 235 and claimed subject matter is not so limited.

In a particular embodiment, process 200 may flow to block 246 where third mask 245 may be removed, a variety of processing methods may be initiated to achieve S/D implant 250 and S/D contacts 248 may be formed.

In a particular embodiment, S/D implants 250 may deviate from standard S/D implants in order to integrate with process 200 because there may be additional STI fill 240 that S/D implants 250 must go through. For example, in a particular embodiment, process 200, S/D implants may be made by: removing extra STI fill 240 when etching second gate material layer 244 at block 242 while third mask 245 is still in place or by removing extra STI fill 240 when a spacer etch is done in a later process step or by implanting through a contact hole, that is, when in subsequent steps S/D contacts 248 are made, a hole may be etched down to the desired S/D implant site and S/D implants 250 may be deposited through the contact hole before the contacts are formed. Implant ions may comprise a variety of materials, such as, for instance, Boron, Arsenic and/or Phosphorus and claimed subject matter is not limited in this regard. However, these are merely examples of various ways process 200 may integrated into a conventional process flow and claimed subject matter is not limited in this regard.

FIG. 3 is a plan view of a particular embodiment of mask 300 that may be used in a combined etch and implant step in a process flow for forming an HV device 100 (illustrated in FIG. 1). In a particular embodiment, mask 300 may be used as described above with reference to FIG. 2 in process 200 at block 222 as first mask 224. In a particular embodiment, DER implantation and polysilicon etch may proceed in a single step through openings 303. However, this is merely an example of a mask that may be used in a combined etch and implant step and claimed subject matter is not limited in this regard.

FIG. 4 is a plan view of a particular embodiment of mask 400 that may be used to define a DER active area and to form STI trenches in a process flow for forming an HV device 100 (illustrated in FIG. 1). In a particular embodiment, mask 400 may be used to define an active area and to define STI boundaries as described above with reference to FIG. 2 in process 200 at block 234 as second mask 236. However, this is merely an example of a mask that may be used in a combined etch and implant step and claimed subject matter is not limited in this regard.

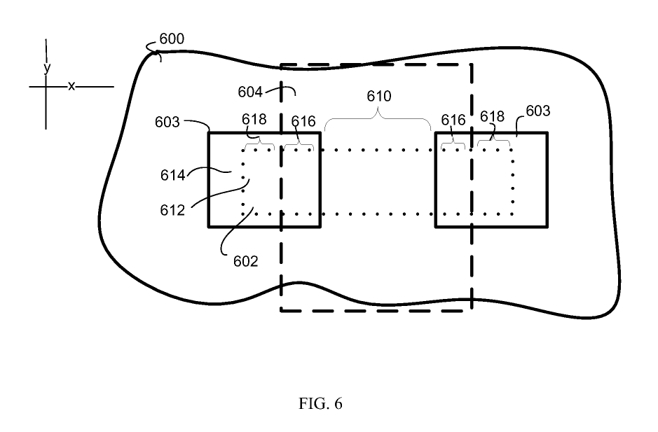

FIG. 5 is a plan view of a particular embodiment of mask 500 that may be used to form a field plate in a process flow for forming an HV device 100 (illustrated in FIG. 1). In a particular embodiment, mask 500 may be used in the above described process 200 at block 242 as third mask 245. However, this is merely an example of a mask used to form a field plate and claimed subject matter is not limited in this regard.

FIG. 6 is a plan view of a particular embodiment of first mask 600, second mask 602, and third mask 604 as described with respect to FIG. 2 and juxtaposed with respect to each other. In a particular embodiment, second mask 602 coverage area extends into openings 603 of first mask 600. According to a particular embodiment, openings 603 may extend beyond an active area into STI trench field 614. In a particular embodiment, masks 602 and 604 may be “clear field masks” wherein only the features to be protected are blocked from the etch by the masking material. In a particular embodiment, mask 602 may define the boundary between DER 612 active area and STI trench field 614. According to a particular embodiment, space 610 between openings 603 may define the first gate length L3 (illustrated in FIG. 2). In a particular embodiment, mask 604 may be juxtaposed relative to mask 600 such that overhangs 616 into openings 603 may define the length L4 of the field plate (illustrated in FIG. 2). Additionally, overhangs 618 may define a space for S/D contacts (illustrated in FIG. 2). According to a particular embodiment, mask 604 may extend beyond DER 612 in the y direction as necessary for circuit interconnection with other devices. However, this is merely an example of a configuration of a variety of masks for use in a process to form an HV device and claimed subject matter is not limited in this regard.

While certain features of claimed subject matter have been illustrated as described herein, many modifications, substitutions, changes and equivalents will now occur to those skilled in the art. It is, therefore, to be understood that the appended claims are intended to cover all such embodiments and changes as fall within the spirit of claimed subject matter.

What is claimed is:

1. A method of forming a microelectronic non-volatile memory cell comprising:
depositing a first gate material layer over a substrate;
performing a ion implant to set a transistor threshold voltage;
applying a first mask, wherein the first mask has two openings and a middle portion having a length L1 in the x direction;
etching the first gate material through the openings of the first mask to remove a portion of the first gate material layer and to form a first gate having a length L1 in the x direction;
implanting ions through the openings of the first mask to form a drain extension region (DER);
depositing a second mask to define an active area and to form shallow trench isolation (STI) trenches adjacent to the first gate;
filling STI trenches with a fill material;
depositing a second layer of gate material above the first gate and filled STI trenches;
applying a third mask over the second layer of gate material, the third mask comprising a coverage area extending beyond the boundaries of the first gate in the x direction; and
etching the second layer of gate material to form a field plate having a length L2 in the x direction wherein the length L1 of the first gate is shorter than the length L2 of the field plate.

2. The method of claim 1 wherein the first gate material layer comprises polysilicon, aluminum or tungsten, or combinations thereof.

3. The method of claim 1 wherein performing the ion implant to set a transistor threshold voltage further comprises implanting boron, arsenic or phosphorus ions, or combinations thereof.

4. The method of claim 1 wherein implanting ions through the openings of the first mask to form the DER further comprises implanting boron, arsenic or phosphorus ions, or combinations thereof to a concentration in the range of about 1×10̂12 ions per cm̂2 to about 1×10̂13 ions per cm̂2.

5. The method of claim 1 wherein the second mask comprises photoresist.

6. The method of claim 1 further comprising recessing STI fill below the level of a top surface of the first gate to adjust the height of the field plate.

7. The method of claim 1 wherein the second gate material layer comprises polysilicon, aluminum or tungsten, or combinations thereof.

8. The method of claim 1 further comprising;
implanting source/drain (S/D) ions; and
forming S/D contacts.

9. The method of claim 1 wherein etching the second gate material further comprises;
removing a portion of STI fill while third mask is still in place to implant source/drain (S/D) ions;
implanting S/D ions; and
forming S/D contacts adjacent to DER.

10. The method of claim 1 further comprising;
forming an S/D contact hole adjacent to DER;
implanting S/D ions through S/D contact hole; and
forming S/D contacts adjacent to DER.

11. A non-volatile memory device comprising:
a memory array region comprising at least one memory cell;
a peripheral region adjacent to the memory array region; and
periphery circuitry located in the peripheral region wherein the periphery circuitry comprises;
at least one high-voltage transistor circuit comprising;
a drain extension region; and
a field plate positioned parallel to the drain extension region and disposed adjacent to the drain extension region.

12. The non-volatile memory device of claim 11 wherein the drain extension region has a length of about 0.25 microns and a width of about 0.25 microns.

13. The non-volatile memory device of claim 11 wherein the memory cell comprises a NAND flash electrically-erasable programmable read only memory cell.

14. The non-volatile memory device of claim 11 wherein the drain extension region comprises an impurity concentration of 1.0×10̂12 ions per cm̂2 to about 1.0×10̂13 ions per cm̂2.
